(19) United States
(12) Patent Application Publication
(10) Pub. No.: US 2018/0100894 A1
(43) Pub. Date: Apr. 12, 2018

(54) Automatic Generation of Test Sequences

(71) Applicants: Larry Venetsky, Mount Laurel, NJ (US); Ross Boczar, Feasterville, PA (US); Russell Shannon, Ocean Gate, NJ (US); Daniel Collins, Toms River, NJ (US); George Lehaf, Holmdel, NJ (US); Steven Singer, Bensalem, PA (US)

(72) Inventors: Larry Venetsky, Mount Laurel, NJ (US); Ross Boczar, Feasterville, PA (US); Russell Shannon, Ocean Gate, NJ (US); Daniel Collins, Toms River, NJ (US); George Lehaf, Holmdel, NJ (US); Steven Singer, Bensalem, PA (US)

(73) Assignee: United States of America as represented by the Secretary of the Navy, Patuxent River, MD (US)

(21) Appl. No.: 15/287,810

(22) Filed: Oct. 7, 2016

(51) Int. Cl. G01R 31/317

(52) U.S. Cl. CPC G01R 31/31703; G01R 31/31718; G01R 31/31704

(57) ABSTRACT

Disclosed here is a system which uses simulations of an electronic circuit and a classifier to create an optimized Test Program Set. A user provides a model of the circuit, including descriptions of common faults. Candidate test signals are simulated in the circuit, evaluated using a classifier and a fitness function which optimizes for fault detection and isolation, and evolved according to a genetic algorithm. The system records the best test signals and terminates after reaching a certain fitness, or after a certain time. The process generates necessary information for an optimized Test Program Set for a given Unit Under Test circuit. This allows test program sets to be generated for complex circuits in a largely automated manner.

### STATEMENT OF GOVERNMENT INTEREST

The invention described herein may be manufactured and used by or for the Government of the United States of America for governmental purposes without payment of any royalties thereon or therefor.

### BACKGROUND

When a test engineer needs to test the operational effectiveness of an electronic circuit, the engineer first has to create a test for that circuit. The engineer must determine a test sequence that will interrogate the circuit. Once the circuit is interrogated, the engineer looks at the output of the circuit to determine whether the circuit has faults. The challenge is to create a good test signal to which the circuit will react accordingly when actual faults exist. If the test sequence is not properly tailored for the circuit being tested, the circuit, often, will not register component faults. That is, circuits with faults (e.g., burned resistors, etc.) will appear as good circuits, as if the fault did not exist (false negative) or the test may show a different fault than the one that is actually there.

Currently, test engineers refer to the specifications of circuits and apply specified frequency sweeps, DC signals, or digital sequences to the particular inputs (or test points) on circuit components to test their effectiveness. The test points for application of frequencies and other test signals are selected through the creation of a Failure Modes, Effects and Criticality Analysis (FMECA), or other types of testability tools and methods. With the application of frequency sweeps and of other pertinent test signals, the engineer will test the circuit and its components, then compare the performance of the tested circuit to that of a known-functional circuit to look for discrepancies between the

Because there are an infinite number of signal combinations during a frequency sweep or test sequence, it is nearly impossible to find an optimal test signal (“optimal” with respect to number of detected or/and isolated faults in a circuit) through the existing manual process. Each component, or set of components, in the circuit has a natural frequency to which it responds and, therefore, individual circuits have different frequencies at which they oscillate. For instance, a filter with a resistor and capacitor has its own oscillating frequency. Furthermore, during operation, the components may physically change due to normal wear and tear leading to considerable deviations from the desired performance. Moreover, each signal has its own time shift with respect to other frequencies. Accordingly, specific component faults in circuits may resonate with a combination of several frequencies and time delays between those frequencies. As a result, for any particular electronic circuit, there is any number of combinations of signals that could work to detect a fault in that circuit.

It is huge undertaking to synthesize a combination of all pertinent frequency signals into one signal that is resonant in a particular circuit to detect a single fault, or single combination of faults. It is time-intensive and labor-intensive process to design a test for an integrated circuit using current methodology described above (specifically in paragraph 3). Furthermore, it is becoming increasingly difficult to find skilled testability engineers to carry out the manual process.

Therefore, what is needed is a novel automated method for finding a specific combination of signals that optimizes a test program set to detect most fault modes in a circuit.

### SUMMARY

The present invention is directed to the needs enumerated above and below.

The present invention is directed to the automatic generation of test sequences or a method for constructing a diagnostic automatic test sequence generator. The method for constructing a diagnostic automatic test sequence and a diagnostics machine to be used in automatic test equipment the method includes: preparing, for a given unit under test (UUT), a computer model capable of simulating that circuit; selecting circuit fault detection parameters and isolation parameters for a simulated circuit; inputting the circuit fault detection parameters and the isolation parameters to create iterations of good simulated circuits and iterations of faulty simulated circuits; inputting the parameters for initial candidate test signals; generating by Genetic Algorithm a population of candidate test input signals, whereby each candidate test input signal is a general waveform signal, comprising of many constituent sine and cosine signals with varying frequencies, phases, durations, and amplitudes; simulating, in the circuit simulator, each of the candidate test input signals to the iterations of good simulated circuits and the iterations of faulty simulated circuits such that simulated circuit output signals are received; assigning, via a classifier that uses the circuit simulator output signals, a performance index for fault isolation and fault detection to each candidate test input signal; checking fault isolation and fault detection performance of each candidate test input signal against search termination criteria; terminating the generating of the candidate fault detection signals and the candidate isolation test signals when one of the candidate test input signals meets termination criteria; and, storing in memory optimized test input signal that meets the termination criteria and storing in memory classifier parameters obtained from using the circuit simulator output signals that meets the termination criteria to construct the diagnostic automatic test sequence generator.

It is a feature of the present invention to provide a method for constructing a diagnostic automatic test sequence generator that results in cost avoidance and time savings.

It is a feature of the present invention to provide a method for constructing a diagnostic automatic test sequence generator that generates test sequences that can be utilized to identify faults in an electronic system.

### DRAWINGS

These and other features, aspects and advantages of the present invention will become better understood with reference to the following description and appended claims, and accompanying drawings wherein:

FIG. 1 is a flow chart depicting the generation of optimum test sequence and diagnostic tester machine;

FIG. 2 is a flow chart depicting the Genetic Algorithm optimization;

FIG. 3 is a figure depicting a Crossover of two individuals produces two offspring within automatic generation of test sequences;

FIG. 4 is a graph showing the input signal and output signal; and,

FIG. 5 is a graph showing the envelope and PSD feature vectors obtained from FIG. 4.

### DESCRIPTION

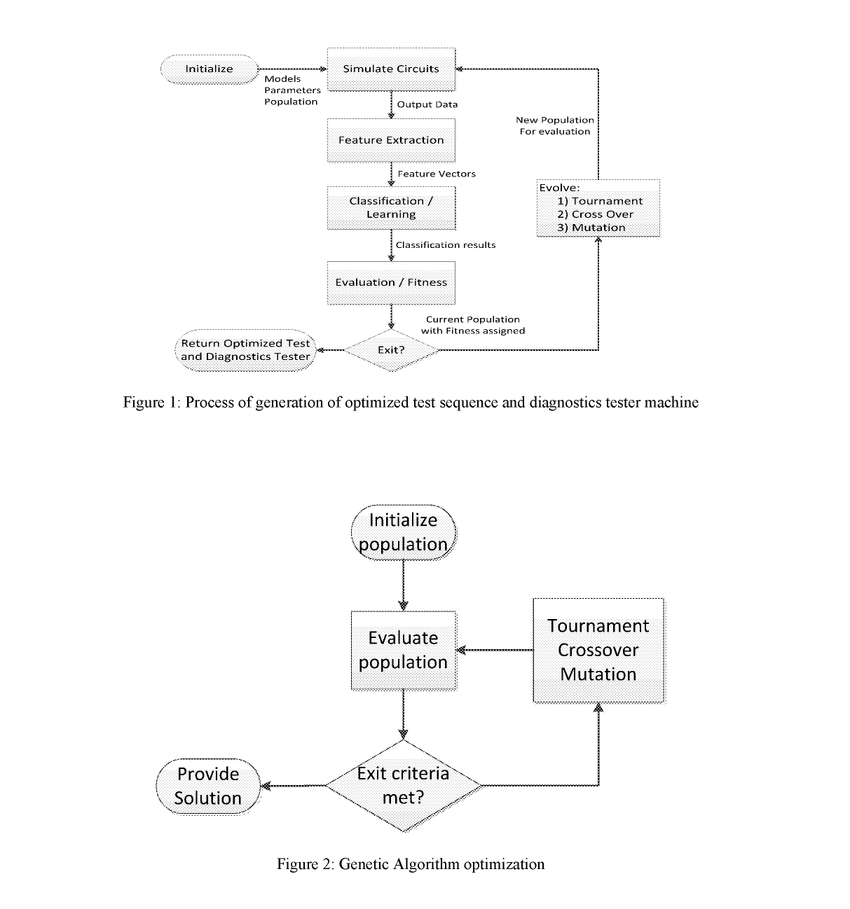

The preferred embodiments of the present invention are illustrated by way of example below and in FIGS. 1-5. The method for constructing a diagnostic automatic test sequence generator and diagnostics machine includes: a) a user interface that makes it possible to define various parameters for extraction of features from “good” and “faulty” circuits models response signals, genetic algorithm, and classifier(s) used in the entire process, b) a circuit simulator which makes it possible to apply a test signal and receive “good” and “faulty” circuit responses, c) an interface allowing the test signal generation process to run the circuit simulator with the “good” and “faulty” circuit models and receive their responses back into the process, d) a circuit model editor allowing to create needed “good” and “faulty” circuit models, e) a genetic algorithm allowing to generate candidate test signals for Unit Under Test “good” and “faulty” circuit models, f) a classifier allowing to generate classes of the response signals from the “good” and “faulty” circuit models, g) a fitness function allowing to use results from the classifier to compute performance index for each of the candidate test signals proposed by the genetic algorithm, h) a computer that runs the entire test signal generation process with memory allowing to store an optimum test signal along with the tester machine specification. The entire process should be able to run in parallel manner on distributed computer network allowing to speed-up test signal optimization and definition of the test machine. Each computer on the network would have a complete set of circuit models with a circuit simulator but would be applying only a portion from the entire test signal candidate population whereby using less time for obtaining “good” and “faulty” circuit model responses. Hence the entire population of test signals would be applied to circuit models in smaller groups. When the responses are obtained, they are all directed to the main machine running the feature extraction, optimization and cost function evaluation of the population of the test signals. When the termination criteria is achieved, then the process stops with retention of the best test signal as well as tester machine design in computer memory. At this point, it is possible to use the tester along with data acquisition (DAQ) hardware interfaces and test signal generators comprising a complete testing machine.

In the description of the present invention, the invention will be discussed in a military environment. However, this invention can be utilized for any type of application that utilizes test sequences.

In the description of the present invention, we will refer to “faults.” However, a particular good or faulty circuit is never just a single point, but a distribution of many components, all within a given tolerance, but never exactly the same. In the present invention, the simulated “good” circuit includes many samples of the circuit, which are perturbed within a given tolerance. The individual “faults” are also not simply a single failing model, but a distribution of faults. For example, a resistor with a nominal value of 100 ohms +/−10% may have a fault where that component is out of tolerance. Rather than simulating only a resistor with a value of 200 ohms, for example, we simulate a range of faulty values. This step is necessary in the preferred embodiment to prevent the phenomenon of “overfitting,” where a classifier will handle the test data perfectly, but will be unable to handle real-world data. In addition to “out of tolerance faults,” there exist so called “hard faults.” Examples of such faults would be “shorted” and “burned open” resistors. In the first case, such a faulty resistor would have a resistance value of 0 ohm. In the latter case, the resistance value would be ∞ (infinite) ohm. Both values if used in numeric simulators (such as LTSpice) may cause numeric problems during an integration routine. In this case, we used values either approaching to 0 or approaching to the ∞ (largest possible number that a given processor can use). In these cases we would represent hard faults as one-sided distributions to account for real-world processes during the test signal optimization reported in this invention.

Genetic Algorithm (GA) and its Application to Search for a Test Signal

In this application all input test signals comprise a population of candidates for the most optimum input test signal. The optimality of the test signal is rated by a Fitness Function assigning some fitness rating to each candidate in the population of test signals. The fitness of a candidate is in direct proportion to the number of detected and isolated faults. The fault is said to be detected when a test signal forces the fault models to produce outputs different from the output of the good circuit model. The fault is said to be isolated if the test signal forces a fault model to output a signal that is different from any other available output of the good or a faulty model. In this method, we are using Genetic Algorithm as a test proposer, and it belongs to the class of stochastic optimization algorithms. The Genetic Algorithm must perform the below listed operations. First it must initialize the population of candidate tests for further optimization. Then the algorithm enters the optimization loop starting with assignment of the fitness value to each of the candidates in the population, followed by selection of the fittest group from the candidates by applying a tournament operator to the population, and then it must produce the next generation of candidate tests through crossover and mutation as shown in FIG. 2.

Using GA terminology, an individual containing a set of parameters is encoded in a chromosome. Each parameter encoded in a gene. Together, these parameters describe an input test signal, but on a computer, they are stored as a binary sequence of ‘1’ and ‘0.’ Below we will discuss the representation of an individual in binary, as well as in the real domain. In pseudo-code notation an individual test may be shown as:
structure indTest{char binRep[BL]; // i.e. ‘110101011000010 . . . ’—chromosome length BL=L*P*N float realRep[RL]; // i.e. {622.309, 5.221, . . . }; —parameters converted from binary representation float fitness=0.65;} // to be assigned by a fitness function
   An array of the “indTest” structures comprises the population of the candidate solutions. In the above structure, L is length of binary string for encoding of each parameter, P is number of parameters per each sequence, and N is number of sequences in each input test signal. In any specific application, it will be necessary to convert the binary representation of a set of the parameters to their real number representation.

To convert from binary to real domain, one must know bounding and maximum values for each of the parameters in an individual test signal and the number of bits in binary representation of this parameter. For example, let us assume that first parameter has minimum allowable value [min =0] and the maximum allowable value [max=1000]. Given the above example with the binary resolution [L=9], it is possible to compute a scale factor as [SF=2̂L=2̂9=512]. Using this scale factor and the boundaries for a parameter, the real number representation of the first binary parameter in this example can be computed in two steps, first converting from binary to integer as [binary_gene=‘110101011’→integer_gene=427] and then by computing real from integer, scale factor and min max limits: [real_gene=min+(integer_gene*max)/2̂L=0+(427*1000)/512=833.98]. This allows the binary data, which the genetic algorithm uses, to be converted to and from the real data, which is the actual parameter that describes the test signal.

Representation of Input Test Signal in GA

An arbitrary waveform of a test signal be represented by multiple sinusoidal periodic waveforms that are added together. Using this fact, a candidate test signal in the circuit simulator is obtained from multiple periodic signals, each defined by some specifications. In the preferred embodiment, we use the SPICE SINE source, which uses the following parameters: (a) Voff—offset voltage of each constituent sinusoid, (b) Vampl—amplitude for each constituent sinusoid, (c) Frequency—frequency for each constituent sinusoid, (d) Tdel—delay time for each constituent sinusoid, (e) Damp—damping for each constituent sinusoid, f) Phase—phase for each constituent sinusoid, (g) Cycle—number of cycles for each constituent sinusoid.

Complete individual specifications for an arbitrary input test signal can be represented as a matrix incorporating the above parameters listed for some number of multiple periodic constituent shown in Table 1. The following matrix is an example of such a signal consisting of three (3) constituent periodic signals:

The above test signal specification is an arbitrary waveform that is defined by three sinusoidal signals, each having seven parameters that are used in the circuit simulator as an input into the circuit models to produce respective outputs. The shown example of an individual test candidate would be represented by 21 parameters matrix as shown above. The number of sinusoidal constituent signals can be changed up or down. The entire population of candidate solutions would consist of multiple such individual candidates for a test signal.

Initialization Operator

The initialization produces a random population of candidate solutions. The initialization is necessary to start the optimization process. The Genetic Algorithm user interface contains the entry fields that a user can populate before running the optimization. The population size, the number of parameters for optimization, the binary length of these parameters, and the number of constituent signals comprising each individual is entered through the UI. These parameters may be the variables listed in Table 1, Fourier Sequence coefficients, or any other means of numerically describing the test signal. An initial random population is established by a uniform distribution random generator that generates random binary individuals representing signal parameters between the minimum and maximum values for each parameter.

A description of the valuation of a candidate solution will be presented later in the section addressing classification methods and their use for assigning the fitness value to each individual. After the initialization and evaluation of the population, the optimization process s the Tournament followed by the Crossover and the Mutation. These operators produce a new population of candidate solutions that are ready for evaluation by a Fitness function, and the process continues until the goal or time limit is reached.

Tournament Operator

The Tournament is the Genetic Algorithm's mechanism to filter out non-fit solutions from the population of candidate tests. Each candidate is evaluated based on its ability to detect and isolate faults. The “score” for that candidate, called its fitness, is ranked against the other candidates. The fitness, tournament surviving probability, and a uniformly distributed random number generator are used in tournament process to select winners. The winning candidates are used to produce the next generation of the candidate solutions through the crossover and mutation operators. In the preferred embodiment, we use a version of the tournament operator where a small, predefined number of best performers are simply copied into the surviving group, and the rest of the population competes among themselves to be placed in this group. The individual with a higher fitness value has a higher chance to be placed in the surviving group, but there is a small chance that an individual with lower fitness may be copied into surviving set. The tournament in this embodiment starts with current population of candidates for the solution. From this set of candidates, the process randomly selects pairs of candidates for selection through tournament. The tournament is conducted by first generating a uniformly distributed random number “p” such that “p” is contained by the interval [0<p<1]. This number is compared with a constant threshold probability “t” such that “t” is usually selected from the interval [0.7<t<1]. If (p<t) then individual with a higher fitness will be copied to the next population of survivors but in the event that (p>t) then an individual with a lower fitness will survive. This process is repeated with next randomly picked pair until the full surviving set is filled. From the above, it is clear that a candidate with higher fitness has higher probability for survival. This fact reflects the biological principle of survival of the fittest, Once the surviving group is established it is used to produce next generation of solutions through the crossover and mutation operators.

Crossover Operator

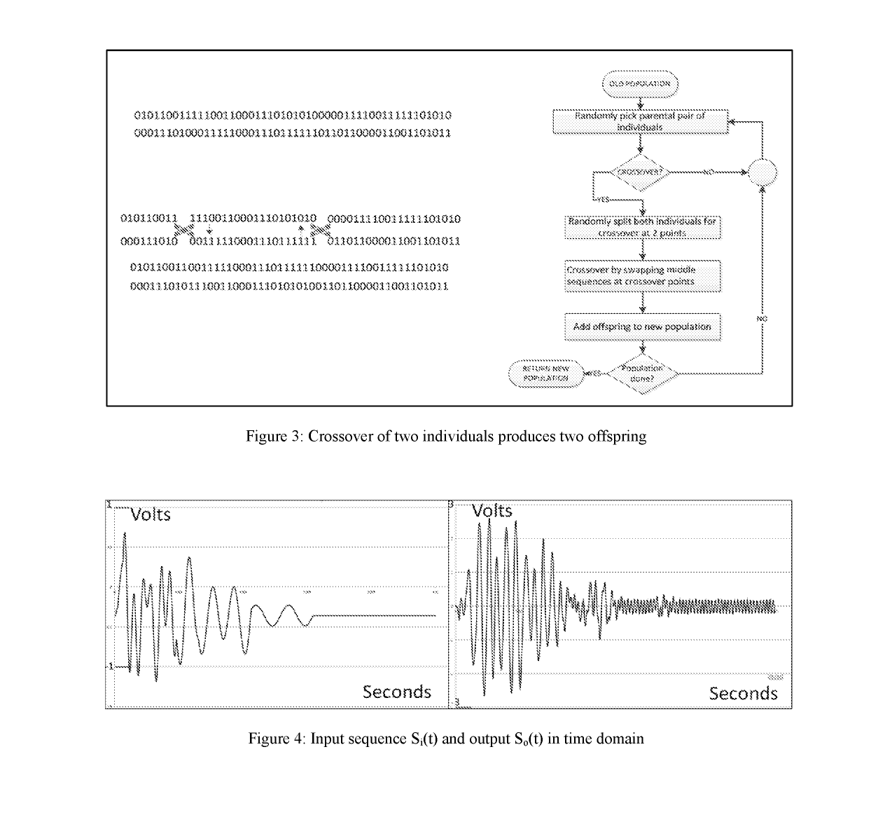

Crossover is the Genetic Algorithm's mechanism to produce a new population of candidate solutions from the previous population of candidate solutions. The crossover is performed to insure that the information (genetic material) about the problem solution is transferred from the parents to the offspring. In our preferred embodiment, the crossover is applied randomly a certain percentage of the time, currently greater than 60%. FIG. 3 illustrates the crossover procedure. The procedure shows randomly picked parental pairs exchanging segments of binary encoding at randomly picked crossover points.

Mutation Operator

Mutation is the Genetic Algorithm's mechanism to resist the convergence tendencies to a dominant solution and provide random sampling opportunities in a search space possibly nudging the optimization to a global optimum as opposed to a local one. Mutation is performed after crossover by iterating through an individual, generating a random value and checking it against mutation probability and flipping the bit value i.e. 0 becomes 1, and 1 becomes 0 if the random value is below the mutation rate. In the preferred embodiment, the mutation probability for each bit is very low (0.1%), however, over many bits per individual and many individuals per population, this low level is sufficient to introduce new “genes” into the population.

Evaluation of Population

Each individual in a population is a test signal Sᵢ(t). It must be propagated through all circuit models to produce their output signals Sₒ(t). Classification of the outputs produces classes for each Sat), The classes returned by a classifier indicate the “goodness” of the test. For instance, if the classifier correctly classifies each Sₒ(t) for every circuit model, then the input signal Sᵢ(t) is “good.” In contrast, if a test signal produced outputs that all look the same and the classifier was not able to separate the output signals then the result of classification would be only one class indicating that this test signal cannot produce unique good and faulty outputs. In the first case, the test signal would get maximum fitness, and in the second case, it would get the lowest fitness. It is very important to use a classifier with high generalization to avoid proliferation of classes caused by producing a separate class for each of the very similar outputs Sₒ(t). Production of separate classes for very similar patterns is referred to as an “overfitting” phenomenon.

The fitness assignment is performed through a two-step process. The first step features extraction from each Sₒ(t), and the second step is done by a classification of the feature vectors, where each feature vector represents an output signal from a model. The classification results are used to determine fitness as a weighted sum of the fault detection percentage [f_{d}], the fault isolation percentage [fᵢ], the ambiguity index [fₐ] as a function of the number and the size of the ambiguity groups, and finally the distance [fᵥ] between desired classification vector and actual classification vector. Fitness F for n^{th} individual can be written as shown in following Equation 1:

$${F}_{n} = {w}_{1} {f}_{d} + {w}_{2} {f}_{i} + {w}_{3} \frac{1}{{f}_{a}} + {w}_{4} \frac{1}{{f}_{v}} = {\sum }_{1}^{k = 4} {w}_{k} f \qquad ( Equation 1 )$$

In Equation 1, the fitness is directly proportional to the detection and isolation coverage and inversely proportional to the number as well as the size of the ambiguity groups, and the distance from the actual and the target classification vectors. Hence the population will be optimized with respect to the fault coverage, ambiguity as well as actual and target classification.

Feat Extraction

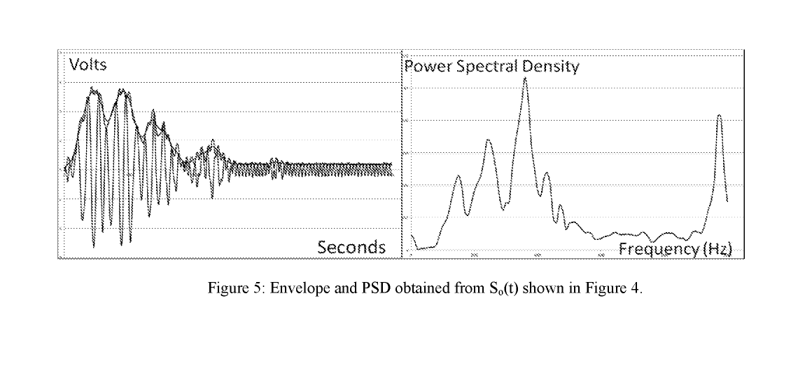

The input test signals Sᵢ(t) and the output model responses Sₒ(t) are represented as a time series of voltage samples. An example such an input and output is shown in FIG. 4. However, the classifiers in use work better with more meaningful features. One example of a feature is the Power Spectral Density (PSD) of the Sₒ(t), which shows the amount of power the signal at a set of frequency bins. Another feature that the use in judging of how well the input signal Sᵢ(t) is performing is the envelope of the output signal Sₒ(t). The envelope of Sₒ(t) can be found by constructing the analytical signal. The analytical signal magnitude of a complex vector where the Sₒ(t) is the real part and the Hilbert transform of the Sₒ(t) is the imaginary part. Fitting a cubic spline curve into the analytic signal establishes another feature set in time domain, Principal Component Analysis is a mathematical tool that attempts to choose the features that best highlight the similarities—and differences—in a particular data set. The present invention can be used with any choice of features.

### Classification

In our preferred embodiment we used Fuzzy Adaptive Resonance Theory (Fuzzy ART) neural network. Fuzzy ART classifies the patterns by way of the Equation 2:

$$\frac{\vert I ⋂ {W}_{k} \vert}{α + \vert {W}_{k} \vert} \qquad ( Equation 2 )$$

This operation is done for each input pattern I producing a vector of output values. The number of values in this vector is equal to the number of classes encoded in Wₖ. Selecting maximum value from the output vector yields the winning node or a class. If the class for current I is not encoded in weight matrix Wₖ , then the current pattern becomes a new class and is added to Wₖ. The decision whether the current input pattern I has a representative encoding is done by the below described rule. If

$$\frac{\vert I ⋂ {W}_{k} \vert}{\vert I \vert} \geq ρ$$

is true then resonance or match occurred and thus pattern I is not added to Wₖ . Instead it is used to slightly modify the existing encoding by:

Wₖ^{new}=β(I∩Wₖ^{old})+(1−β)Wₖ^{old} (Equation 3)

Otherwise the pattern I is added to Wₖ by way of adding a new row “j” to the weight matrix wⱼ^{new}=(I∩Wⱼ^{old}). In Equations 2 and 3, I is a current input pattern, ρ is a vigilance parameter that determines classifier's ability to generalize, β is a learning parameter, and Wₖ is a neural network weight matrix containing the classes representing the circuit faults. We obtained the input pattern I by augmenting first norm of Sₒ(t) with its complement {1−|Sₒ(t)|} such that

I=[|Sₒ(t)|, {1−|Sₒ(t)|}] (Equation 4)

The selected classifier is run on each input signal, and the results are used to compute the fitness of that input signal. First, the features selected above are stored. For each input signal, there are many sets of features—one for each “good” and “faulty” circuit model. Each feature also corresponds to a “label”—either “0,” for the good models, or the number of the fault, for the faulty models. First, each feature set is assigned to either the “training” set or the “test” set. The size of each set can be chosen by the user. Second, the training set is used to train the classifier. Third, the classifier is run on the test set. The labels returned by the classifier are compared to the actual labels. This process may be repeated until each feature set has been part of both the “training” set and the “test” set at least once.

Finally, the fitness is calculated using a combination of the fault detection (the percentage of the time that a faulty feature set was classified as faulty, or a good feature set was classified as good), the fault isolation (the percentage of the time that a feature set was classified to the correct label), and a cost function (which may include the time, complexity, or resources needed by the test set). The fitness values will be used to create the next generation of test signals.

### Techniques Using Multiple Signals

Most commercial and military applications will require a Test Program Set (TPS) including multiple input signals. To allow sets of multiple test programs to be evolved together, an alternative method of running the classifier and computing the fitness is described. A parameter, N, represents the size of the population of test signals. A second parameter, k, represents the number of test programs to be included in each TPS. The term k may be set by the user as a constant, or may be controlled by the system—for example, it may be incremented if the fitness seems to “stagnate” over a certain number of generations.

As before, each individual signal is simulated in each “good” and “faulty” circuit model, and the results are recorded. However, the classifier is now run on Test Program Sets instead of individual signals. A list of TPSs is generated either exhaustively (where all N choose k=(N!)/(k!*(N−k)!) TPSs are represented), or where combinations of signals are chosen randomly err from a list entered by the user. Each TPS is a list of k signals. Each TPS is run through the classifier, as described above, and a fitness for that TPS is calculated. Then, each signal's fitness is calculated using the maximum fitness of the TPSs that it is part of. Finally, when building the next generation of input signals, at least the k best signals should be copied over, so that the entire best TPS is able to compete in the next generation.

This has the advantage of evaluating the TPS as a whole. Selecting for individual signal fitness may help detect many of the faults, but other faults may require a specialized input signal to detect. When selecting for individual fitness, the signals that isolate hard-to-detect faults and very little else will be drowned out by the signals that isolate a greater number of easy-to-detect faults. Selecting for fitness of a group—the TPS—allows a symbiotic relationship between the constituent test signals.

### Termination Criteria

After the current population of candidate solutions was evaluated and each of the individuals was assigned a fitness index, the best performer may be selected and be used for checking if the goal of the optimization was reached. Two examples of reasons to terminate the optimization are reaching a specified fitness or exceeding a specified allowable time limit.

The method for constructing a diagnostic automatic test sequence and a diagnostics machine to be used in automatic test equipment the method includes: preparing, for a given unit under test (UUT), a computer model capable of simulating a circuit; selecting circuit fault detection parameters and isolation parameters for a simulated circuit; inputting the circuit fault detection parameters and the isolation parameters to create iterations of good simulated circuits and iterations of faulty simulated circuits; inputting parameters for initial candidate test signals; generating by a Genetic Algorithm a population of candidate test input signals, whereby each candidate test input signal is a general waveform signal, comprising of many constituent sine and cosine signals with varying frequencies, phases, durations, and amplitudes; simulating, in a circuit simulator, each of the candidate test input signals to the iterations of good simulated circuits and the iterations of faulty simulated circuits such that simulated circuit output signals are received; assigning, via a classifier that uses the circuit simulator output signals, a performance index for fault isolation and fault detection to each candidate test input signal; checking fault isolation and fault detection performance of each candidate test input signal against search termination criteria; terminating the generating of the candidate test input signals when one of the candidate test input signals meets termination criteria; and, storing in memory an optimized test input signal that meets the termination criteria and storing in memory classifier parameters obtained from using circuit simulator output signals that meets the termination criteria to construct a diagnostic automatic test sequence generator.

The circuit is described by a computer model, which the user will prepare. In the current embodiment, this is a SPICE netlist describing each component of the circuit, including how they are connected, and how they behave. The model must describe each component and how they are connected, as well as the inputs and outputs of the circuit. From the basic model, a number of faulty models are also prepared. The faulty simulated circuits may be provided by an engineer, based on knowledge of the likely failure modes, based on historical maintenance or diagnostic data, where the fault may consist of anything the simulator is able to accept, involving any number of components, Alternatively, the faulty simulated circuits may instead be generated by the system itself, by randomly choosing components to consider “faulty,” and randomly choosing them as either “open circuits,” “short circuits,” or “wrong component” errors.

From these “ideal” circuits, where all components have nominal values, it is necessary to create a “range” of good and faulty circuits. Providing this variation by perturbing the values of each component is important because it forces the classifier to differentiate between the variance caused by the tolerance of the components and the variance caused by an actual fault. This has been shown to improve real-world specificity and sensitivity, as no real component has precisely the nominal value. In one of the embodiments of the invention, a range of good simulated circuits may be generated by the system itself by mutating the value of each component, such that each component remains within a specified tolerance, but such that many slightly different good circuits may be produced. A range of faulty simulated circuits may be generated by the diagnostic automatic test sequence generator, or may be inputted into the system such that each fault is a distribution of sample circuits. The initial candidate test signals may be provided by an engineer based on manual work, based on previous successful signals, based on another engineering method.

In one of the embodiments of the invention, the Genetic Algorithm may perform any combination of crossover and mutation operators, including copying some individuals from a previous generation without modification or generating entirely new individuals, and randomly choosing to apply crossover, mutation, or both, to build the rest of the new generation of signals from the previous generation. The circuit simulator may be a SPICE simulator, and where the system may automatically produce SPICE models containing each good and faulty circuit and each candidate signal. The faulty circuits may be built and attached to the computer using a Data Acquisition device, where every simulation step is performed on a physical circuit, by selecting which faults are being simulated in a specially-designed circuit card by use of switching elements such as relays or transistors. Prior to passing the data to the classifier, the dimensionality of the data may be first reduced, using manual features such as DC bias, Power Spectral Density, the signal's Envelope; a Fourier Transform; Principal Component Analysis. The classifier may be added to the system as a “plug-in,” such that it provides a function to “train” a classifier on certain data, and a function to “test” or “rim” the classifier on other data. The parameters may be specified either automatically or by the user to be passed on to the classifier. The classifier may be first trained on a certain percentage of the circuits and then tested against remaining circuits, and the training and testing process is repeated a fixed number of times, before returning an average or total fitness. The test set may be only one signal and the process may be repeated until circuit has been used as a test circuit at least once. The fitness may use fault detection, fault isolation, the existence and size of ambiguity groups, and is modified by other variables determined by the test engineer. Additionally, the search termination criteria may be a certain percentage of faults detected, a certain percentage of faults isolated, a certain fitness, a certain number of generations, a certain run ti The population of test signals may be evaluated together, as complete Test Program Sets, rather than individual test programs, and the fitness for each signal is computed based on the fitness of TPSs that it is part of. One or more steps may be distributed to multiple computers or CPU cores and executed in parallel.

When introducing elements of the present invention or the preferred embodiment thereof, the articles “a,” “an,” “the,” and “said” are intended to mean there are on ore of the elements. The terms “comprising,” “including,” and “having” are intended to be inclusive and mean that there may be additional elements other than the listed elements.

Although the present invention has been described in considerable detail with reference to certain preferred embodiments thereof, other embodiments are possible. Therefore, the spirit and scope of the appended claims should not be limited to the description of the preferred embodiment(s) contained herein.

What is claimed is:

1. A method for constructing a diagnostic automatic test sequence and a diagnostics machine to be used in automatic test equipment the method comprising:
preparing, for a given unit under test (UM), a computer model capable of simulating a circuit;
selecting circuit fault detection parameters and isolation parameters for a simulated circuit;
inputting the circuit fault detection parameters and the isolation parameters to create iterations of good simulated circuits and iterations of faulty simulated circuits;
inputting parameters for initial candidate test signals;
generating by a Genetic Algorithm a population of candidate test input signals, whereby each candidate test input signal is a general waveform signal, comprising of many constituent sine and cosine signals with varying frequencies, phases, durations, and amplitudes;
simulating, in a circuit simulator, each of the candidate test input signals to the iterations of good simulated circuits and the iterations of faulty simulated circuits such that simulated circuit output signals are received;
assigning, via a classifier that uses the circuit simulator output signals, a performance index for fault isolation and fault detection to each candidate test input signal;
checking fault isolation and fault detection performance of each candidate test input signal against search termination criteria;
terminating the generating of the candidate test input signals when one of the candidate test input signals meets termination criteria; and,
storing in memory an optimized test input signal that meets the termination criteria and storing in memory classifier parameters obtained from using circuit simulator output signals that meets the termination criteria to construct a diagnostic automatic test sequence generator.

2. The method of claim 1, where the method utilizes a SPICE netlist describing each component of the circuit.

3. The method of claim 2, where the faulty simulated circuits is provided by an engineer, based on knowledge of the likely failure modes, based on historical maintenance or diagnostic data, where the fault may consist of anything the simulator is able to accept, involving any number of components.

4. The method of claim 2, where the faulty simulated circuits is generated by the system itself, by randomly choosing components to consider “faulty,” and randomly choosing them as either “open circuits,” “short circuits,” or “wrong component” errors.

5. The method of claim 4, where a range of good simulated circuits is generated by the itself by mutating the value of each component, such that each component remains within a specified tolerance, but such that many slightly different good circuits may be produced.

6. The method of claim 5, where a range of faulty simulated circuits may be generated by the diagnostic automatic test sequence generator.

7. The method of claim 5, where a range of faulty simulated circuits is inputted such that each fault is a distribution of sample circuits.

8. The method of claim 7, where the initial candidate test signals is provided by an engineer based on manual work, based on previous successful signals, or based on another engineering method.

9. The method of claim 7, where the initial candidate test signals is generated randomly by the diagnostic automatic test sequence generator.

10. The method of claim 5, where the Genetic Algorithm performs any combination of crossover and mutation operators, including copying some individuals from a previous generation without modification or generating entirely new individuals, and randomly choosing to apply crossover, mutation, or both, to build the rest of the new generation of signals from the previous generation.

11. The method of claim 10, where the circuit simulator is a SPICE simulator, and where the system automatically produces SPICE models containing each good and faulty circuit and each candidate signal.

12. The method of claim 10, where the faulty circuits are built and attached to the computer using a Data Acquisition device, where every simulation step is performed on a physical circuit, by selecting which faults are being simulated in a specially-designed circuit card by use of switching elements such as relays or transistors.

13. The method of claim 12, where prior to passing the data to the classifier, the dimensionality of the data t reduced, using manual features such as DC bias, Power Spectral Density, the signal's Envelope; a Fourier Transform; Principal Component Analysis.

14. The method of claim 13, where any type of classifier can be added to the system as a “plug-in,” such that it provides a function to “train” a classifier on certain data, a function to “test” or “run” the classifier on other data, and optionally, a function to configure the classifier.

15. The method of claim 14, where parameters is specified either automatically or by the user to be passed on to the classifier.

16. The method of claim 15, where the classifier is first trained on a certain percentage of circuits and then tested against remaining circuits, and the training and testing process is repeated a fixed number of times, before returning an average or total fitness.

17. The method of claim 16, where the test set is only one signal and the process is repeated until each circuit has been used as a test circuit at least once.

18. The method of claim 17, where the fitness uses fault detection, fault isolation, the existence and size of ambiguity groups, and is modified by other variables determined by the test engineer.

19. The method of claim 1 8, where the search termination criteria is a certain percentage of faults detected, a certain percentage of faults isolated, a certain fitness, a certain number of generations, a certain run time.

20. The method of claim 19, where the population of test signals are evaluated together, as complete Test Program Sets, rather than individual test programs, and the fitness for each signal is computed based on the fitness of TPSs that it is part of.

21. The method of claim 20, where one or more steps is distributed to multiple computers or CPU cores and executed in parallel.

22. The method of using the generated Test Program Set, the method further comprising:
connecting to the unit under test;
loading a suitable test program set;
performing each test in the test program set and collecting the results;
processing the results as described in the test program set;
propagating the processed results through a classifier described in the test program set; and,
reporting the results to the use.
